(19) United States
(12) Patent Application Publication
(10) Pub. No.: US 2023/0378277 A1
(43) Pub. Date: Nov. 23, 2023

(54) BIDIRECTIONAL POWER TRANSISTOR AND METHOD FOR PRODUCING A BIDIRECTIONAL POWER TRANSISTOR

(71) Applicant: Robert Bosch GmbH, Stuttgart (DE)

(72) Inventor: Jens Baringhaus, Sindelfingen (DE)

(21) Appl. No.: 18/314,230

(22) Filed: May 9, 2023

(30) Foreign Application Priority Data
May 19, 2022 (DE) 10 2022 205 006.1

(51) Int. Cl. H01L 29/20; H01L 29/66; H01L 29/778

(52) U.S. Cl. CPC H01L 29/2003; H01L 29/66462; H01L 29/7786

(57) ABSTRACT

A bidirectional power transistor. The bidirectional power transistor has an AlGaN/GaN structure, a first gate structure and a second gate structure. A surface of the AlGaN/GaN structure has a depression having a first slanting sidewall and a second slanting sidewall. The depression has a width that is greater than a height of the depression. The first gate structure is situated on the first slanting sidewall and the second gate structure is situated on the second slanting sidewall.

### CROSS REFERENCE

The present application claims the benefit under 35 U.S.C. § 119 of German Patent Application No. DE 10 2022 205 006.1 filed on May 19, 2022, which is expressly incorporated herein by reference in its entirety.

### FIELD

The present invention relates to a bidirectional power transistor and to a method for producing a bidirectional power transistor.

### BACKGROUND INFORMATION

Power transistors on a gallium nitride basis make it possible to realize components providing low closing resistances and high break-through voltages at the same time. Widely available are so-called high-electron mobility transistors, in which the current flow takes place laterally at the substrate surface with the aid of two-dimensional electron gas. Bidirectional power transistors can be produced using these lateral components. This means that the characteristic curve of the power transistor is able to be operated in a fully symmetrical manner so that the power transistor can conduct and block in two directions.

A drawback in this context is that such bidirectional power transistors have only low threshold voltages in the range of fewer than 1.5 V. For safety-critical applications, this is not enough to reliably prevent a parasitic connection of the transistor in a dynamic operation.

An object of the present invention is to overcome this disadvantage.

### SUMMARY

According to an example embodiment of the present invention, the bidirectional power transistor has an AlGaN/GaN structure, a first gate structure, and a second gate structure. According to the present invention, a surface of the AlGaN/GaN structure has a depression having a first slanting sidewall and a second slanting sidewall, the depression having a width that is greater than a height of the depression, and the first gate structure is situated on the first slanting sidewall and the second gate structure is situated on the second slanting sidewall. In other words, the two gates of the power transistor are positioned on slanting flanks.

This is advantageous insofar as the charge carrier density within the two-dimensional electron gas is lowered locally so that the threshold voltage is increased.

In a refinement of the present invention, an angle of the first slanting sidewall and an angle of the second slanting sidewall has a value ranging from 30° to 60° to a transverse direction in each case.

This offers the advantage that the charge carrier density is optimally lowered. In other words, the two-dimensional electron gas becomes very depleted or more strongly depleted so that a greater gate voltage is required to refill it again with charge carriers.

In a further embodiment of the present invention, the angle of the first slanting sidewall and the angle of the second slanting sidewall are equal in terms of their absolute value.

This has the advantage of providing a symmetrical behavior of the power transistor, that is, of ensuring the most identical threshold voltage in both directions in a bidirectional operation.

According to an example embodiment, the bidirectional power transistor has an AlGaN/GaN structure, a first gate structure, and a second gate structure. According to the present invention, a surface of the AlGaN/GaN structure has a first V-shaped depression and a second V-shaped depression, and the first gate structure is situated on the first V-shaped depression and the second gate structure is positioned on the second V-shaped depression.

This offers the advantage that identical crystal facets are present underneath each gate electrode so that the threshold voltages of the two gates have a greater symmetry.

In a further embodiment of the present invention, the bidirectional power transistor is a lateral HEMT.

A method for producing a bidirectional power transistor according to an example embodiment the present invention includes producing a depression having a first slanting sidewall and a second slanting sidewall on an undoped GaN layer and applying an undoped AlGaN layer to the undoped GaN layer with the aid of epitaxy. In addition, the present method includes applying a first gate structure to the first slanting sidewall and applying a second gate structure to the second slanting sidewall.

This may have the advantage that the two gate structures are able to be applied both simultaneously by the same process flow and in different process flows. This is advantageous especially if the first and the second sidewall have physically different properties which can be compensated for by a different development of the first and the second gate electrode so that the best symmetrical switching behavior of the component is achieved.

Additional advantages result from the following description of exemplary embodiment embodiments of the present invention.

### BRIEF DESCRIPTION OF THE DRAWINGS

In the following text, the present invention will be described in greater detail based on preferred embodiments and the figures.

FIG. 1 shows a first exemplary embodiment of a bidirectional power transistor, according to the present invention.

FIG. 2 shows a second exemplary embodiment of a bidirectional power transistor, according to the present invention.

FIG. 3 shows a transfer characteristic curve of the bidirectional power transistor according to the first exemplary embodiment, according to the present invention.

FIG. 4 shows a method for producing a bidirectional power transistor according to the first exemplary embodiment of the present invention.

### DETAILED DESCRIPTION OF EXAMPLE EMBODIMENTS

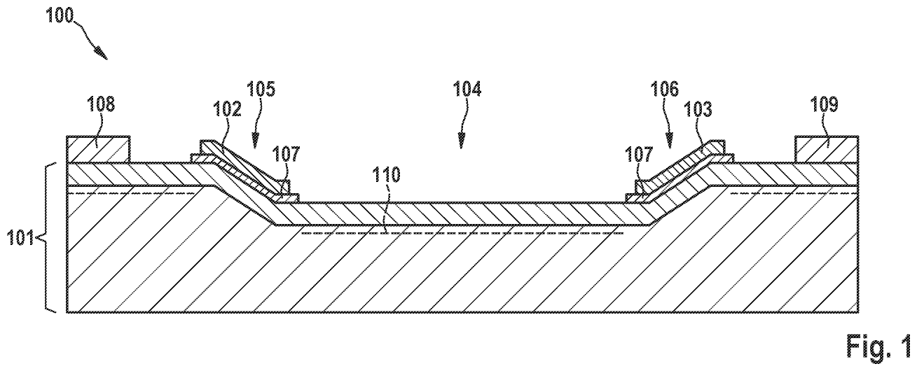

FIG. 1 shows a first exemplary embodiment of a bidirectional power transistor 100. Bidirectional power transistor 100 includes an AlGaN/GaN structure 101 in which a thin, undoped AlGaN layer is situated on an undoped GaN layer, and a first gate structure 102 and a second gate structure 103. A surface of the AlGaN/GaN structure 101 includes a depression 104 with a first slanting sidewall 105 and a second slanting sidewall 106. Depression 104 has a width that is greater than a height of depression 104. A p-doped region 107 is situated on first slanting sidewall 105 and second slanting sidewall 106 in each case. P-doped region 107 may include AlGaN or GaN. Situated on first slanting sidewall 105 above p-doped region 107 is first gate structure 102. Situated on second slanting sidewall 106 above p-doped region 107 is second gate structure 103. A first electrode 108 and a second electrode 109 are situated on AlGaN/GaN structure 101, first electrode 108 and second electrode 109 functioning as a source electrode and a drain electrode as a function of the current direction, so that when a voltage is applied, a current flow takes place in the vicinity of the junction between the AlGaN layer and the GaN layer within the GaN layer through a two-dimensional electron gas 110. In other words, a region between first electrode 108 and second electrode 109 is lowered, and first gate structure 102 and second gate structure 103 are situated between first electrode 108 and second electrode 109, and first gate structure 102 and second gate structure 103 are separated from the AlGaN layer by p-doped regions 107. GaN is a polar material whose charge carrier density in two-dimensional electron gas 110 varies as a function of the angle relative to the GaN surface. At angles that are greater than 0°, the charge carrier density continuously decreases and is zero at 90°. Due to the angle, two-dimensional electron gas 110 is heavily depleted so that the threshold voltage of bidirectional power transistor 100 is high. The task of the p-doped regions 107 is to locally deplete two-dimensional electron gas 110 so that no charge carriers are present underneath first gate structure 102 and second gate structure 103 as long as no positive voltage is applied at first gate structure 102 or second gate structure 103. In this state, bidirectional power transistor 100 is normally-off. By applying gate voltages above the threshold voltage at first gate structure 102 and second gate structure 103, the bidirectional power transistor is able to be switched to conductive in both directions between first electrode 108 and second electrode 109. As an alternative, it is possible to apply a gate voltage only at first gate structure 102 or at second gate structure 103 so that bidirectional power transistor 100 can be blocked in one direction.

In one exemplary embodiment, an angle of first slanting sidewall 105 and an angle of second slanting sidewall 106 has a value ranging from 30° to 60° relative to a transverse direction. The transverse direction denotes the direction that is situated at a right angle to the propagation direction or stack direction of AlGaN/GaN structure 101.

In a further exemplary embodiment, the angles of first slanting sidewall 105 and second slanting sidewall 106 are equal in terms of their absolute value.

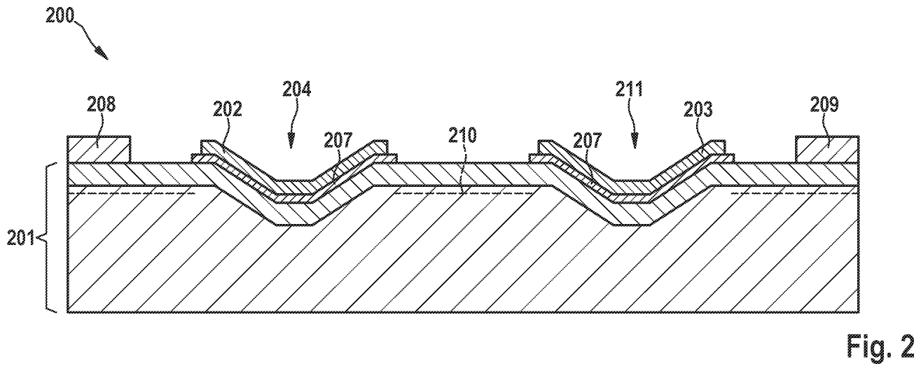

FIG. 2 shows a second exemplary embodiment of a bidirectional power transistor 200. Bidirectional power transistor 200 includes an AlGaN/GA structure 201, in which a thin, undoped AlGaN layer is situated on an undoped GaN layer, as well as a first gate structure 202 and a second gate structure 203. A surface of AlGaN/GaN structure 201 has a first V-shaped depression 204 and a second V-shaped depression 211. A width of first V-shaped depression 204 is less than a height of first V-shaped depression 204, and a width of second V-shaped depression 211 is less than a height of second V-shaped depression 211. First gate structure 202 is situated on first V-shaped depression 204, and second gate structure 203 is situated on second V-shaped depression 211.

In one exemplary embodiment, first V-shaped depression 204 and second V-shaped depression 211 are of equal size.

Bidirectional power transistor 100 and 200 is designed as a lateral HEMT.

Bidirectional power transistors 100 and 200 are used in power electronics such as in an electric drive train of electric vehicles or hybrid vehicles. In addition, they are used in chargers and DCDC converters of electric vehicles or hybrid vehicles, and also in inverters of household appliances such as washing machines.

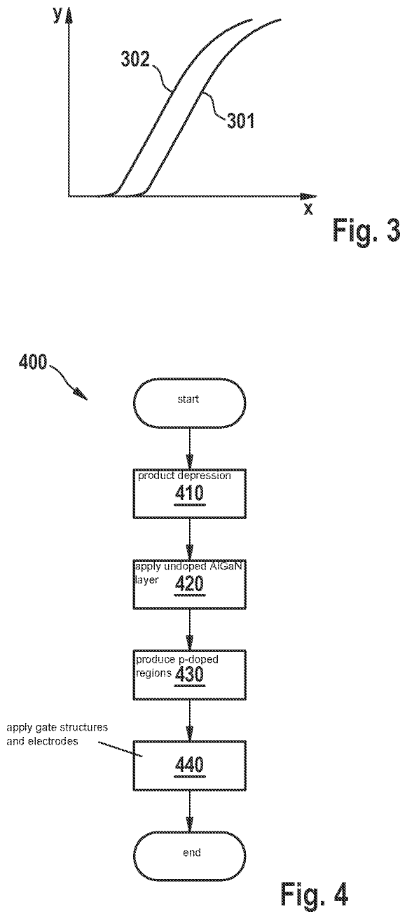

FIG. 3 shows a transfer characteristic curve 301 of bidirectional power transistor 100 according to the first exemplary embodiment. The x-axis shows the gate voltage, and the y-axis shows the drain current. For comparison purposes, curve 302 shows a transfer characteristic curve from the related art in which the two gate electrodes, the drain electrode, and the source electrode, are situated on a planar surface. The bidirectional power transistor from the related art is already conductive when a low gate voltage is applied. In bidirectional power transistor 100 according to the present invention, the conductivity sets in at a clearly higher gate voltage so that this bidirectional power transistor is suitable for safety-critical applications.

FIG. 4 shows a method 400 for producing a bidirectional power transistor. Method 400 starts with a step 410 in which a depression having a first slanting sidewall and a second slanting sidewall is produced on an undoped GaN layer. In a following step 420, using epitaxy, an undoped AlGaN layer is applied on top of the undoped GaN layer. In a following step 430, p-doped regions are produced on the first slanting sidewall and the second slanting sidewall. In a following step 440, a first gate structure is applied to the first slanting sidewall above the p-doped region, a second gate structure is applied to the second slanting sidewall above the p-doped region, a first electrode is applied to the undoped AlGaN layer, and a second electrode is applied to the undoped AlGaN layer. Alternatively, the second gate structure is able to be applied to the second slanting sidewall above the p-doped region in a following step, which is not shown in FIG. 4.

What is claimed is:

1. A bidirectional power transistor, comprising:
an AlGaN/GaN structure;
a first gate structure; and
a second gate structure;
wherein a surface of the AlGaN/GaN structure has a depression having a first slanting sidewall and a second slanting sidewall, the depression having a width that is greater than a height of the depression, and the first gate structure is situated on the first slanting sidewall and the second gate structure is situated on the second slanting sidewall.

2. The bidirectional power transistor as recited in claim 1, wherein an angle of the first slanting sidewall and an angle of the second slanting sidewall each has a value ranging from 30° to 60° to a transverse direction.

3. The bidirectional power transistor as recited in claim 2, wherein the angle of the first slanting sidewall and the angle of the second slanting sidewall are equal in terms of their absolute value.

4. A bidirectional power transistor, comprising:
an AlGaN/GaN structure;
a first gate structure; and
a second gate structure;
wherein a surface of the AlGaN/GaN structure has a first V-shaped depression and a second V-shaped depression, and the first gate structure is situated on the first V-shaped depression and the second gate structure is situated on the second V-shaped depression.

5. The bidirectional power transistor as recited in claim 4, wherein the bidirectional power transistor is a lateral HEMT.

6. A method for producing a bidirectional power transistor, the method comprising the following steps:
producing, along a transverse direction, a depression having a first slanting sidewall and a second slanting sidewall on an undoped GaN layer;
applying an undoped AlGaN layer to the undoped GaN layer using epitaxy; and
applying a first gate structure to the first slanting sidewall and applying a second gate structure to the second slanting sidewall.
